(19) United States
(12) Patent Application Publication
(10) Pub. No.: US 2026/0186037 A1
(43) Pub. Date: Jul. 2, 2026

(54) ELECTRODE RESISTANCE MEASURING DEVICE

(71) Applicant: LG Energy Solution, Ltd., Seoul (KR)

(72) Inventors: Hyuk Kim, Daejeon (KR); Hyeok Jeong, Daejeon (KR); Kyun Il Rah, Daejeon (KR)

(21) Appl. No.: 18/861,854

(22) PCT Filed: Oct. 17, 2023
(86) PCT No.: PCT/KR2023/016018

§ 371 Date: Oct. 30, 2024

(30) Foreign Application Priority Data
Dec. 20, 2022 (KR) 10-2022-0178973

(51) Int. Cl. G01R 27/16

(52) U.S. Cl. CPC G01R 27/16

(57) ABSTRACT

Electrode resistance measuring devices are provided which measure the through-plane resistance of an electrode and enables single-sheet measurement for individual electrodes with high reproducibility, the device comprising: an upper terminal whose bottom surface is in close contact with an upper surface of a measurement target electrode; a lower terminal of which the top surface is in close contact with the bottom surface of an electrode to be measured; and a resistance measurement unit electrically connected to an upper terminal and the lower terminal so as to measure the resistance of the electrode to be measured, wherein microporous layers are formed on the bottom surface of the upper terminal and the top surface of the lower terminal.

### CROSS-REFERENCE TO RELATED APPLICATIONS

This application is a National Phase entry pursuant to 35 U.S.C. § 371 of International Application No. PCT/KR2023/016018 filed on Oct. 17, 2023, which claims priority to and the benefit of Korean Patent Application No. KR 10-2022-0178973, filed on Dec. 20, 2022. The contents of the above-identified applications are herein incorporated by reference in their entireties.

### TECHNICAL FIELD

The present disclosure relates to electrode resistance measuring apparatuses, and to electrode resistance measuring apparatuses that enable single-sheet measurement of individual electrodes with high reproducibility in measuring through-plane resistance of the electrodes.

### BACKGROUND

Methods for measuring the resistance of electrodes or auxiliary materials prepared for secondary batteries, fuel cells, etc., are divided into an in-plane resistance measurement method and a through-plane resistance measurement method.

When driving an actual battery, the through-plane resistance of the electrode that matches the direction in which electrons flow is directly related to the performance of the battery.

In addition, through-plane resistance measurement makes it possible to identify non-uniformity in the vertical direction of the electrode coated using a wet coating method, and may be applied to quality control of batteries.

As shown in FIG. 1, existing through-plane resistance measurement may be performed by, after attaching a pair of terminals 1101 and 1102 for measuring the resistance of an electrode 1011 to both sides of the electrode 1011, respectively, applying current to both terminals 1101 and 1102 through a power supply device 1200 and measuring the resistance thereto. Contact portions of the terminals 1101 and 1102 for measuring electrode resistance may be formed as flat surfaces. At this time, due to high contact resistance between the electrode 1011 and the terminals 1101 and 1102, the reproducibility of the through-plane resistance measurement is poor.

According to a related art, in order to increase the reproducibility of the through-plane resistance measurement, there was a method of stacking several electrodes and then pressing them with high pressure. This measurement method also had difficulty in obtaining uniform values due to contact unevenness due to accumulated contact resistance and steps between multiple electrodes and between the outermost electrode and the terminal. In addition, an analysis method performed by stacking multiple electrodes had difficulty in analyzing characteristics of individual electrodes.

There is a need for a through-plane resistance measurement technology with excellent reproducibility that solves the above problems, which is capable of measurement for individual electrodes.

The background description provided herein is for the purpose of generally presenting context of the disclosure. Unless otherwise indicated herein, the materials described in this section are not prior art to the claims in this application and are not admitted to be prior art, or suggestions of the prior art, by inclusion in this section.

### SUMMARY

The present disclosure relates to electrode resistance measuring apparatuses, and provides electrode resistance measuring apparatuses that enable single-sheet measurement of individual electrodes with high reproducibility in measuring through-plane resistance of the electrodes.

Technical objects to be achieved by the present disclosure are not limited to the technical objects mentioned above, and other technical tasks that are not mentioned will be clearly understood by those skilled in the art from the description below.

An electrode resistance measuring apparatus of the present disclosure may comprise: an upper terminal comprising a bottom surface, the bottom surface of the upper terminal contacting a measurement target electrode; a lower terminal comprising an upper surface, the upper surface of the lower terminal contacting the measurement target electrode; and a resistance measuring unit electrically coupled to the upper terminal and to the lower terminal, wherein the bottom surface of the upper terminal may comprise a first microporous layer and the upper surface of the lower terminal comprises a second microporous layer.

In an electrode resistance measuring apparatus of the present disclosure, the first or the second microporous layer may comprise at least of carbon, a conductive metal, or a conductive polymer.

In an electrode resistance measuring apparatus of the present disclosure, the first microporous layer may comprise a bottom surface of a conductive pressure plate comprising a rigid material coated with or bonded to: (1) first fine particles with a D50 of 5 μm or less or (2) a first fine fiber network with a width of 10 μm or less, the second microporous layer may comprise an upper surface of a conductive support plate comprising a rigid material coated with or bonded to: (1) second fine particles with a D50 of 5 μm or less or (2) a second fine fiber network with a width of 10 μm or less, and the first fine particles, the second fine particles, the first fine fiber network, or the second fine fiber network may comprise at least one of a transition metal, aluminum, carbon, or a conductive polymer.

In an electrode resistance measuring apparatus of the present disclosure, the upper terminal may comprise: a conductive pressure plate comprising a first conductive material, the first conductive material having a planar bottom surface, the planar bottom surface perpendicular to a vertical direction; and a first gas diffusion layer (GDL) fixed to the planar bottom surface of the conductive pressure plate, and the lower terminal may comprise a conductive support plate comprising a second conductive material, the second conductive material having a planar upper surface, the planar upper surface perpendicular to the vertical direction; and a second GDL fixed to the planar upper surface of the conductive support plate, and wherein a first conductive paste fixes the first GDL to the conductive pressure plate and a second conductive paste fixes the second GDL to the conductive support plate.

In an electrode resistance measuring apparatus of the present disclosure, the conductive pressure plate and the conductive support plate may comprise at least one of a transition metal, aluminum, or carbon.

In an electrode resistance measuring apparatus of the present disclosure, the first GDL and the second GDL may each comprise a carbon fiber layer.

In an electrode resistance measuring apparatus of the present disclosure, an upper surface of the carbon fiber layer of the first GDL may adhere to the bottom surface of the conductive pressure plate by the first conductive paste, the first microporous layer is located on a bottom surface of the carbon fiber layer of the first GDL, a bottom surface of the carbon fiber layer of the second GDL may adhere to the upper surface of the conductive support plate by the second conductive paste, and the second microporous layer is located on an upper surface of the carbon fiber layer of the second GDL.

In an electrode resistance measuring apparatus of the present disclosure, the first or second conductive paste may comprise conductive particles, binder, and solvent in a paste state, the conductive particles of the first conductive paste or the second conductive paste may comprise at least one of carbon black, graphite, carbon nanotube (CNT), graphene, a transition metal, or aluminum, and the conductive particles of the first conductive paste or the second conductive paste have a D₅₀ of 20 μm or less.

In an electrode resistance measuring apparatus of the present disclosure, the first conductive paste and the second conductive paste may be 20 μm to 200 μm thick.

In an electrode resistance measuring apparatus of the present disclosure, a porosity of the first microporous layer of the first GDL may be 30% to 80% and a porosity of the second microporous layer of the second GDL may be 30% to 80%.

In an electrode resistance measuring apparatus of the present disclosure, the first microporous layer of the first GDL may be 20 μm to 150 μm thick and the second microporous layer of the second GDL may be 20 μm to 150 μm thick.

In an electrode resistance measuring apparatus of the present disclosure, a load body may be located on an upper surface of the upper terminal.

In an electrode resistance measuring apparatus of the present disclosure, the upper terminal and the load body may be disk-shaped.

An electrode resistance measuring apparatus of the present disclosure measures the through-plane resistance of electrodes, which may enable single-sheet measurement of individual electrodes with high reproducibility.

An electrode resistance measuring apparatus of the present disclosure may minimize contact resistance between electrodes and terminals when measuring the through-plane resistance.

The electrode resistance measuring apparatus of the present disclosure may obtain resistance measurement values for individual electrodes in a state where contact resistance is minimized by forming a microporous conductive layer on a surface of the terminal in contact with the electrode, completely adhering to a rough surface of the individual electrode.

### BRIEF DESCRIPTION OF THE DRAWINGS

The accompanying drawings illustrate various embodiments of the present disclosure and together with the foregoing disclosure, serve to provide further understanding of the technical features of the present disclosure, and thus, the present disclosure is not construed as being limited to the drawings.

FIG. 1 is a perspective view illustrating a through-plane resistance measurement method according to a related art.

FIG. 2 is a perspective view illustrating an embodiment of an electrode resistance measuring apparatus of the present disclosure.

FIG. 3 is a cross-sectional view illustrating a state in which an upper terminal and a lower terminal are in close contact with a measurement target electrode.

FIG. 4 is a perspective view illustrating another embodiment of an electrode resistance measuring apparatus of the present disclosure.

FIG. 5 is a graph illustrating through-plane resistance measurement values according to Examples 1 and 2 and Comparative Example.

### DETAILED DESCRIPTION

An electrode resistance measuring apparatus of the present disclosure may include:
an upper terminal whose bottom surface is in close contact with an upper surface of a measurement target electrode;
a lower terminal whose upper surface is in close contact with a lower surface of the measurement target electrode; and
a resistance measuring unit electrically connected to the upper terminal and the lower terminal to measure a resistance of the measurement target electrode,
wherein microporous layers may be formed on the bottom surface of the upper terminal and the upper surface of the lower terminal.

In an electrode resistance measuring apparatus of the present disclosure, a material of the microporous layers may include at least one or more of carbon, conductive metal, and conductive polymer.

In an electrode resistance measuring apparatus of the present disclosure, the microporous layer of the upper terminal may be formed by coating or bonding fine particles with a D₅₀ of 5 μm or less or a fine fiber network with a width of 10 μm or less to a bottom surface of a conductive pressure plate made of a rigid material, the microporous layer of the lower terminal may also be formed by coating or bonding fine particles with a D₅₀ of 5 μm or less or a fine fiber network with a width of 10 μm or less to an upper surface of a conductive support plate made of a rigid material, and a material of the fine particles or the fine fiber networks coated or bonded to the upper terminal and the lower terminal may include at least one or more of transition metal, aluminum, carbon, and conductive polymer.

In an electrode resistance measuring apparatus of the present disclosure, the upper terminal may include a conductive pressure plate made of a conductive material and having a bottom surface formed as a plane perpendicular to a vertical direction, and a first gas diffusion layer (GDL) fixed to the bottom surface of the conductive pressure plate, and the lower terminal may include a conductive support plate made of a conductive material and having an upper surface formed as a plane perpendicular to the vertical direction, and a second GDL fixed to the upper surface of the conductive support plate, wherein conductive paste may fix the first GDL and the conductive pressure plate between them and the second GDL and the conductive support plate between them.

In an electrode resistance measuring apparatus of the present disclosure, a material of the conductive pressure plate and the conductive support plate may include at least one or more of transition metal on a periodic table, aluminum, and carbon.

In an electrode resistance measuring apparatus of the present disclosure, the first GDL and the second GDL may include a microporous layer and a carbon fiber layer.

In an electrode resistance measuring apparatus of the present disclosure, an upper surface of a carbon fiber layer of the first GDL may be adhered to the bottom surface of the conductive pressure plate by the conductive paste, a microporous layer may be stacked on a bottom surface of the carbon fiber layer of the first GDL, a bottom surface of a carbon fiber layer of the second GDL may be adhered to the upper surface of the conductive support plate by the conductive paste, and a microporous layer may be stacked on an upper surface of the carbon fiber layer in the second GDL.

In an electrode resistance measuring apparatus of the present disclosure, the conductive paste may be obtained by mixing conductive particles, binder, and solvent in a paste state, a material of the conductive particles of the conductive paste may include at least one or more of carbon black, graphite, carbon nanotube (CNT), graphene, transition metal, and aluminum, and a size of the conductive particles of the conductive paste may be D₅₀ of 20 μm or less.

In an electrode resistance measuring apparatus of the present disclosure, the conductive paste may be formed to a thickness of 20 μm to 200 μm between the first GDL and the conductive pressure plate and between the second GDL and the conductive support plate.

In an electrode resistance measuring apparatus of the present disclosure, a porosity of the microporous layer of the first GDL and the microporous layer of the second GDL may be 30% to 80%.

In an electrode resistance measuring apparatus of the present disclosure, a thickness of the microporous layer of the first GDL and the microporous layer of the second GDL may be 20 μm to 150 μm.

In an electrode resistance measuring apparatus of the present disclosure, a load body for pressing the measurement target electrode may be stacked on an upper surface of the upper terminal.

In an electrode resistance measuring apparatus of the present disclosure, each of the upper terminal and the load body may be provided in a disk shape.

Hereinafter, embodiments according to the present disclosure will be described in detail with reference to the attached drawings. In this process, the size or shape of the components shown in the drawings may be exaggerated for clarity and convenience of explanation.

In the description of the present disclosure, it should be noted that an orientation or positional relationship indicated by the terms such as “center”, “upper”, “lower”, “left”, “right”, “vertical”, “horizontal”, “inner side”, “outer side”, “one side”, and “other side” is based on an orientation or positional relationship shown in a drawing or an orientation or positional relationship that is placed when using the product of the present disclosure on a daily basis, and is merely for explanation and brief description of the present disclosure, and it does not suggest or imply that the displayed device or element must necessarily be configured or operated in a specified orientation and should not be construed as limiting the present disclosure.

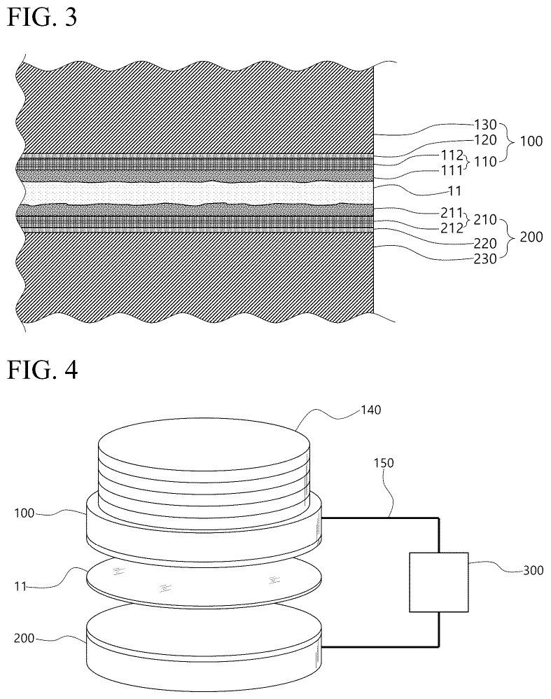

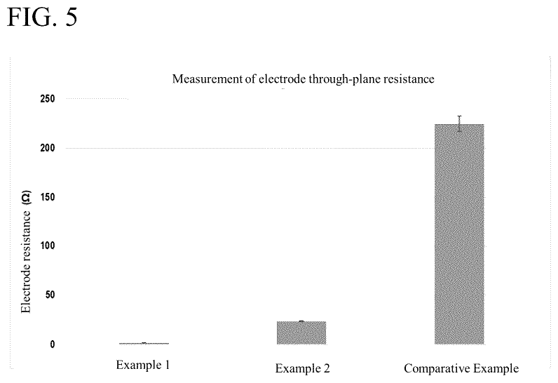

FIG. 2 is a perspective view illustrating an embodiment of an electrode resistance measuring apparatus of the present disclosure. FIG. 3 is a cross-sectional view illustrating a state in which an upper terminal 100 and a lower terminal 200 are in close contact with a measurement target electrode 11. FIG. 4 is a perspective view illustrating another embodiment of an electrode resistance measuring apparatus of the present disclosure. FIG. 5 is a graph illustrating through-plane resistance measurement values according to Examples 1 and 2 and Comparative Example.

Hereinafter, with reference to FIGS. 2 to 5, the electrode resistance measuring apparatus of the present disclosure will be described in detail. Hereinafter, in the description, a vertical direction may be the direction of gravity.

Electrode resistance measuring apparatuses of the present disclosure may be capable of measuring through-plane resistance with high reproducibility for individual electrodes.

As shown in FIG. 2, the electrode resistance measuring apparatus of the present disclosure may include:
the upper terminal 100 whose bottom surface is in close contact with an upper surface of the measurement target electrode 11;
the lower terminal 200 whose upper surface is in close contact with a lower surface of the measurement target electrode 11; and
a resistance measuring unit 300 electrically connected to the upper terminal 100 and the lower terminal 200 to measure a resistance of the measurement target electrode 11,
wherein microporous layers 111 and 211 may be formed on the bottom surface of the upper terminal 100 and the upper surface of the lower terminal 200.

In an electrode resistance measuring apparatus of the present disclosure, the measurement target electrode 11 may be provided in a planar shape perpendicular to the vertical direction. Specifically, the measurement target electrode 11 may be made of a conductive material and may be provided in the shape of a plate or sheet. For example, the measurement target electrode 11 may be formed by applying electrode slurry to Cu foil or Al foil and then drying it. The electrode slurry may be obtained by mixing an active material, a conductive material, a binder, and a solvent in a paste state, or may be obtained by mixing a conductive material, a binder, and a solvent in a paste state to improve the adhesion between an electrode containing an active material and a conductive foil as a current collector. At this time, the surface on which the electrode slurry is dried may be rough depending on the situation and may not be formed as an ideal plane.

As shown in FIGS. 2 and 4, the area of the bottom surface of the upper terminal 100 or the upper surface of the lower terminal 200 may be formed to be equal to or smaller than the area of the measurement target electrode 11. In an electrode resistance measuring apparatus of the present disclosure, since the bottom surface of the upper terminal 100 and the upper surface of the lower terminal 200 are formed of the microporous layers 111 and 211 and the thickness of the measurement target electrode 11 may be formed very thin, the upper terminal 100 and the lower terminal 200 may be in direct contact when the area of the bottom surface of the upper terminal 100 and the upper surface of the lower terminal 200 are formed larger than the area of the measurement target electrode 11. Accordingly, it may be desirable for the area of the bottom surface of the upper terminal 100 or the upper surface of the lower terminal 200 to be formed equal to or smaller than the area of the measurement target electrode 11.

In an electrode resistance measuring apparatus of the present disclosure, the microporous layer (111, 211) may be formed by applying a carbon paste to a carbon fiber layer (112, 212) such as carbon paper, followed by drying and heat treatment. The carbon paste, which is formed into the microporous layer (111, 211) after the drying and heat treatment, may be obtained by mixing carbon powder, fluororesin, water, and alcohol.

The resistance measuring unit 300 of the present disclosure may include a current supply that supplies input current between the upper terminal 100 and the lower terminal 200, and a voltmeter that measures the voltage between the upper terminal 100 and the lower terminal 200. The input current is not limited to alternating current or direct current and may vary depending on the analysis purpose. The resistance measuring unit 300 may be electrically connected to each of the upper terminal 100 and the lower terminal 200 through a conductive cable 150.

As shown in FIG. 3, in an electrode resistance measuring apparatus of the present disclosure, the upper terminal 100 may include a conductive pressure plate 130 made of a conductive material and having a bottom surface formed as a plane perpendicular to a vertical direction, and a first gas diffusion layer (GDL) 110 fixed to the bottom surface of the conductive pressure plate 130, and the lower terminal 200 may include a conductive support plate 230 made of a conductive material and having an upper surface formed as a plane perpendicular to the vertical direction, and a second GDL 210 fixed to the upper surface of the conductive support plate 230.

In addition, conductive paste 120 and 220 may fix the first GDL 110 and the conductive pressure plate 130 between them and the second GDL 210 and the conductive support plate 230 between them.

An electrode resistance measuring apparatus of the present disclosure may, by fixing the conductive pressure plate 130 and the first GDL 110, and the conductive support plate 230 and the second GDL 210, which are made of different materials, with the conductive paste 120 and 220, prevent the relative positions between each other from changing and prevent contact conditions from changing at interfaces by filling voids at the interfaces between each other with the conductive paste 120 and 220. Specifically, after applying the conductive paste 120 to the bottom surface of the conductive pressure plate 130 or the upper surface of the first GDL, the conductive pressure plate 130 and the first GDL 110 may be brought into close contact with each other and then dried to fix the conductive pressure plate 130 and the first GDL 110 to each other. Similarly, after applying the conductive paste 220 between the conductive support plate 230 and the second GDL 210, the conductive support plate 230 and the second GDL 210 may be brought into close contact with each other and then dried to fix the conductive support plate 230 and the second GDL 210 to each other.

The material of the conductive pressure plate 130 and the conductive support plate 230 may include at least one or more of a transition metal on the periodic table, aluminum, and carbon. For example, the transition metal may be SUS, copper, titanium, nickel, etc. As another example, the conductive pressure plate 130 and the conductive support plate 230 may be made by coating the surface of a rigid material with a conductive material such as gold. In other words, the conductive pressure plate 130 and the conductive support plate 230 may be made of a rigid conductive material. The conductive pressure plate 130 and the conductive support plate 230 may be brought into close contact with the measurement target electrode 11 by pressing the conductive pressure plate downward with the measurement target electrode 11 in between, in a state where the bottom surface of the conductive pressure plate 130 and the upper surface of the conductive support plate 230 are arranged to face each other.

The first GDL 110 and the second GDL 210 may include the microporous layers 111 and 211 and the carbon fiber layers 112 and 212. As described above, the first GDL 110 and the second GDL 210 may be prepared by applying carbon paste to the carbon fiber layers 112 and 212 such as carbon paper, followed by drying and heat treatment to form the microporous layers 111 and 211. The carbon paste, which is formed into the microporous layer (111, 211) after the drying and heat treatment, may be obtained by mixing carbon powder, fluororesin, water, and alcohol. The fluororesin may be one or more selected from the group consisting of polytetrafluoroethylene (PTFE), tetrafluoroethylene-perfluoroalkyl vinyl ether copolymer (PFA), tetrafluoroethylene-hexafluoropropylene copolymer (FEP), polychlorotrifluoroethylene (PCTFE), tetrafluoroethylene-ethylene copolymer (ETFE), and polyfluorobinylidene (PVDF).

The carbon fiber layer (112, 212) may be formed of carbon fiber. The carbon fiber (CF) may be a fibrous carbon material with a mass content of carbon element of 90% or more. Specifically, carbon fiber may be a fiber that has mostly a graphite structure obtained by pyrolysis of an organic precursor (material before carbonization) fiber. In addition, the carbon fiber layer (112, 212) may be coated with fluororesin.

As shown in FIG. 3, an upper surface of the carbon fiber layer 112 of the first GDL 110 may be adhered to the bottom surface of the conductive pressure plate 130 by the conductive paste 120, the microporous layer 111 may be stacked on a bottom surface of the carbon fiber layer 112 of the first GDL 110, a bottom surface of the carbon fiber layer 212 of the second GDL 210 may be adhered to the upper surface of the conductive support plate 230 by the conductive paste 220, and the microporous layer 211 may be stacked on an upper surface of the carbon fiber layer 212 in the second GDL 210. In other words, the electrode resistance measuring apparatus of the present disclosure may, by adhering the carbon fiber layers 112 and 212 of the GDLs with the conductive paste 120 and 220 to the conductive pressure plate 130 and the conductive support plate 230, which are made of materials that are advantageous for forming a flat surface with high-quality smoothness, and bringing the microporous layers 111 and 211 of the GDLs into close contact with surfaces of the measurement target electrode 11 which have poor smoothness, improve reproducibility when measuring through-plane resistance by minimizing contact resistance.

The conductive paste (120, 220) may be obtained by mixing conductive particles, binder, and solvent in a paste state. The material of the conductive particles of the conductive paste (120, 220) may include at least one or more of carbon black, graphite, carbon nanotube (CNT), graphene, transition metal, and aluminum. The size of the conductive particles of the conductive paste (120, 220) may be D₅₀ of 20 μm or less.

The conductive paste (120, 220) may be formed to a thickness of 20 μm to 200 μm between the first GDL 110 and the conductive pressure plate 130 and between the second GDL 210 and the conductive support plate 230. The thickness of the conductive paste 120 and 220 may be determined considering the state of the carbon fiber layers 112 and 212 or the smoothness of the conductive pressure plate 130 and the conductive support plate 230.

The porosity of the microporous layer 111 of the first GDL 110 and the microporous layer 211 of the second GDL 210 may be 30% to 80%. More preferably, the porosity of the microporous layer 111 of the first GDL 110 and the microporous layer 211 of the second GDL 210 may be 40% to 70%. The microporous layer 111 of the first GDL 110 and the microporous layer 211 of the second GDL 210 may have a thickness of 20 μm to 150 μm.

As another embodiment, the microporous layer of the upper terminal may be formed by coating or bonding fine particles with a D₅₀ of 5 μm or less or a fine fiber network with a width of 10 μm or less to the bottom surface of the conductive pressure plate made of a rigid material. In addition, the microporous layer of the lower terminal may also be formed by coating or bonding fine particles with a D₅₀ of 5 μm or less or a fine fiber network with a width of 10 μm or less to an upper surface of a conductive support plate made of a rigid material. At this time, the material of the fine particles or the fine fiber network coated or bonded to the upper terminal and the lower terminal may include at least one or more of transition metal, aluminum, carbon, and conductive polymer.

As shown in FIG. 4, a load body 140 for pressing the measurement target electrode 11 may be stacked on an upper surface of the upper terminal 100. The load body 140 may be provided in plurality. In measuring through-plane resistance, the amount of pressure applied to the measurement target electrode 11 by the upper terminal 100 may affect the measurement results. Therefore, it is necessary to pressurize the measurement target electrode 11 with an appropriate level of pressure, and in an electrode resistance measuring apparatus of the present disclosure, the pressure with which the upper terminal 100 presses the measurement target electrode 11 may be adjusted by adjusting the number of load bodies 140. The pressure with which the upper terminal 100 presses the measurement target electrode 11 may preferably be 0.01 kgf/cm² to 0.2 kgf/cm². If the pressure with which the upper terminal 100 presses the measurement target electrode 11 is less than 0.01 kgf/cm², the contact resistance may increase and measurement precision may decrease, and if the pressure with which the upper terminal 100 presses the measurement target electrode 11 exceeds 0.2 kgf/cm², the thickness of the measurement target electrode 11 may change, affecting the measured value.

The upper terminal 100 and the load body 140 may be provided in a disk shape. For accurate measurement in an electrode resistance measuring apparatus of the present disclosure, it may be important that the upper terminal 100 is not tilted. Accordingly, the upper terminal 100 and the load body 140 may be provided in a disk shape so as not to have anisotropy with respect to the direction perpendicular to the vertical direction. The upper terminal 100 may be provided with an alignment means for aligning the center of the load body 140 with the center of the upper terminal 100. The alignment means may be a projection, a groove, a marker, or the like. The conductive cable 150 for electrical connection between the upper terminal 100 and the resistance measuring unit 300 may be laterally coupled to the upper terminal 100 so as not to interfere with stacking of the load body 140.

### EXAMPLE 1

The cathode of the lithium secondary battery was prepared as the measurement target electrode 11 with a size of 19.6 cm².

The conductive pressure plate 130 and the conductive support plate 230 were made of SUS material, and the total weight of the upper terminal 100 and the load body 140 was prepared to be 0.3 kg. The first GDL 110 and the second GDL 210 were prepared with Sigracet 39 BC from SGL.

The conductive paste 120 and 220 was applied between the conductive pressure plate 130 and the first GDL 110 and between the conductive support plate 230 and the second GDL 210 and then dried, so that the conductive pressure plate 130 and the first GDL 110 and the conductive support plate 230 and the second GDL 210 were fixed to each other.

As the resistance measuring unit 300, Hioki BT3563 HiTESTER from Hioki Corporation was used. An alternating current of 1 kHz was applied as an input current between the upper terminal 100 and the lower terminal 200.

After the measurement target electrode 11 was completely separated from the upper terminal 100 and the lower terminal 200, the measurement was repeated three times.

### EXAMPLE 2

The cathode of the lithium secondary battery was prepared as the measurement target electrode 11 with a size of 19.6 cm².

The conductive pressure plate 130 and the conductive support plate 230 were made of SUS material, and the total weight of the upper terminal 100 and the load body 140 was prepared to be 0.3 kg. The first GDL 110 and the second GDL 210 were prepared with Sigracet 39 BC from SGL.

The conductive pressure plate 130 and the first GDL 110 and the conductive support plate 230 and the second GDL 210 were directly in close contact without being fixed with conductive paste therebetween.

As the resistance measuring unit 300, Hioki BT3563 HiTESTER from Hioki Corporation was used. An alternating current of 1 kHz was applied as an input current between the upper terminal 100 and the lower terminal 200.

After the measurement target electrode 11 was completely separated from the upper terminal 100 and the lower terminal 200, the measurement was repeated three times.

### COMPARATIVE EXAMPLE

The cathode of the lithium secondary battery was prepared as the measurement target electrode 11 with a size of 19.6 cm².

The conductive pressure plate 130 and the conductive support plate 230 were made of SUS material, and the total weight of the upper terminal 100 and the load body 140 was prepared to be 0.3 kg.

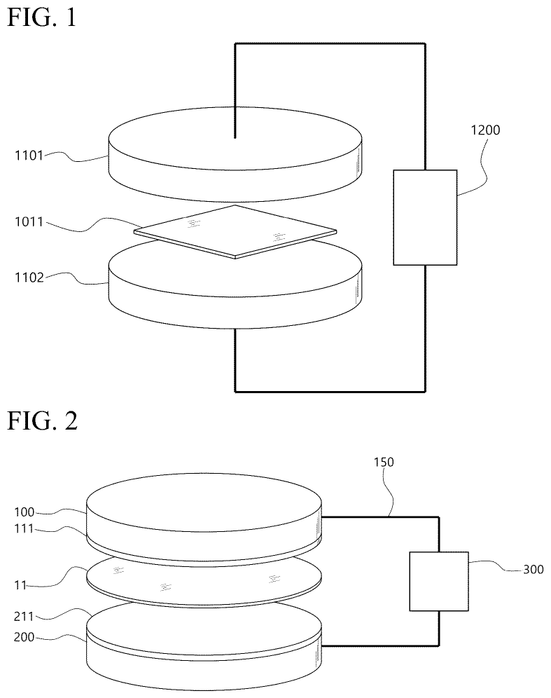

As shown in FIG. 1, the conductive pressure plate 130 and the measurement target electrode 11 and the conductive support plate 230 and the measurement target electrode 11 were directly in close contact without GDL insertion therebetween.

As the resistance measuring unit 300, Hioki BT3563 HiTESTER from Hioki Corporation was used. An alternating current of 1 kHz was applied as an input current between the upper terminal 100 and the lower terminal 200.

After the measurement target electrode 11 was completely separated from the upper terminal 100 and the lower terminal 200, the measurement was repeated three times.

The resistance value shown in FIG. 5 may be an average value for repeated measurements. As shown in FIG. 5, in through-plane resistance measurement, when the microporous layer 111, 211 is present on the surface of the terminal in contact with the measurement target electrode 11, it may be seen that the measured resistance value rapidly decreases. In particular, in the case of Example 1 and Comparative Example, it may be seen that the measured resistance values differ by about 50 times or more. This is because contact resistance that interferes with measurement has been minimized. In addition, as a result of calculating the precision for Examples 1 and 2 and Comparative Example, it was calculated to be 0.55%, 2.36%, and 3.55%, respectively. In other words, Examples 1 and 2 showed excellent precision compared to the Comparative Example, and in particular, Example 1 achieved excellent reproducibility with a precision of 0.55%.

The precision was calculated as a percentage of the standard deviation value relative to the average value of electrode resistance.

Although embodiments according to the present disclosure have been described above, they are merely illustrative, and those skilled in the art will understand that various modifications and embodiments of an equivalent scope are possible therefrom. Therefore, the true technical protection scope of the present disclosure should be determined by the appended claims.

### EXPLANATION OF SYMBOLS

11 . . . Measurement target electrode, 100 . . . Upper terminal, 110 . . . First GDL, 111 . . . Microporous layer, 112 . . . Carbon fiber layer, 120 . . . Conductive paste, 130 . . . Conductive pressure plate, 140 . . . Load body, 150 . . . Conductive cable, 200 . . . Lower terminal, 210 . . . Second GDL, 211 . . . Microporous layer, 212 . . . Carbon fiber layer, 220 . . . Conductive paste, 230 . . . Conductive support plate, 300 . . . Resistance measuring unit

An electrode resistance measuring apparatus of the present disclosure measures the through-plane resistance of electrodes, which may enable single-sheet measurement of individual electrodes with high reproducibility.

An electrode resistance measuring apparatus of the present disclosure may minimize contact resistance between the electrodes and terminals when measuring the through-plane resistance.

An electrode resistance measuring apparatus of the present disclosure may obtain resistance measurement values for individual electrodes in a state where the contact resistance is minimized by forming a microporous conductive layer on the surface of the terminal in contact with the electrode, completely adhering to the rough surface of the individual electrode.

1. An electrode resistance measuring apparatus comprising:
an upper terminal whose bottom surface is in close contact with an upper surface of a measurement target electrode;
a lower terminal whose upper surface is in close contact with a lower surface of the measurement target electrode; and
a resistance measuring unit electrically coupled to the upper terminal and to the lower terminal,
wherein microporous layers are formed on the bottom surface of the upper terminal and the upper surface of the lower terminal.

2. The electrode resistance measuring apparatus of claim 1, wherein a the microporous layers comprises at least one of carbon, a conductive metal, or a conductive polymer.

3. The electrode resistance measuring apparatus of claim 1, wherein the microporous layer of the upper terminal is formed by coating or bonding fine particles with a D₅₀ of 5 μm or less or a fine fiber network with a width of 10 μm or less to a bottom surface of a conductive pressure plate made of a rigid material,
the microporous layer of the lower terminal is also formed by coating or bonding fine particles with a D₅₀ of 5 μm or less or a fine fiber network with a width of 10 μm or less to an upper surface of a conductive support plate made of a rigid material, and
a material of the fine particles or the fine fiber networks coated or bonded to the upper terminal and the lower terminal comprise at least one of a transition metal, aluminum, carbon, or a conductive polymer.

4. The electrode resistance measuring apparatus of claim 1, wherein the upper terminal comprises:
a conductive pressure plate comprising a conductive material and having a bottom surface formed as a plane perpendicular to a vertical direction; and
a first gas diffusion layer (GDL) fixed to the bottom surface of the conductive pressure plate, and
wherein the lower terminal comprises:
a conductive support plate comprising a conductive material and having an upper surface formed as a plane perpendicular to the vertical direction; and
a second GDL fixed to the upper surface of the conductive support plate, and
wherein conductive paste fixes the first GDL and the conductive pressure plate between them and the second GDL and the conductive support plate between them.

5. The electrode resistance measuring apparatus of claim 4, wherein the conductive pressure plate and the conductive support plate comprise at least one of a transition metal aluminum, or carbon.

6. The electrode resistance measuring apparatus of claim 4, wherein the first GDL and the second GDL each comprise a microporous layer and a carbon fiber layer.

7. The electrode resistance measuring apparatus of claim 6, wherein an upper surface of the carbon fiber layer of the first GDL adheres to the bottom surface of the conductive pressure plate by the conductive paste,
the microporous layer is located on a bottom surface of the carbon fiber layer of the first GDL,
a bottom surface of the carbon fiber layer of the second GDL adheres to the upper surface of the conductive support plate by the conductive paste, and
the microporous layer is located on an upper surface of the carbon fiber layer of the second GDL.

8. The electrode resistance measuring apparatus of claim 7, wherein the conductive paste comprises conductive particles, binder, and solvent in a paste state,
the conductive particles of the conductive paste comprises at least one of carbon black, graphite, carbon nanotube (CNT), graphene, a transition metal, or aluminum, and
the conductive particles of the conductive paste have a D₅₀ of 20 μm or less.

9. The electrode resistance measuring apparatus of claim 8, wherein the conductive paste is formed to a thickness of 20 μm to 200 μm between the first GDL and the conductive pressure plate and between the second GDL and the conductive support plate.

10. The electrode resistance measuring apparatus of claim 7, wherein a porosity of the microporous layer of the first GDL and the microporous layer of the second GDL is 30% to 80%.

11. The electrode resistance measuring apparatus of claim 7, wherein the microporous layer of the first GDL is 20 μm to 150 μm thick and the microporous layer of the second GDL is 20 μm to 150 μm thick.

12. The electrode resistance measuring apparatus of claim 3, wherein a load body is located on an upper surface of the upper terminal.

13. The electrode resistance measuring apparatus of claim 12, wherein the upper terminal and the load body are disk-shaped.
